(19) United States
(12) Patent Application Publication
(10) Pub. No.: US 2007/0018311 A1
(43) Pub. Date: Jan. 25, 2007

(54) Circuit board and light souce device having same

(75) Inventor: Jen-Tsorng Chang, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/432,743

(22) Filed: May 10, 2006

(30) Foreign Application Priority Data
Jul. 8, 2005 (CN) 200510035933.5

(51) Int. Cl. H01L 23/34

(52) U.S. Cl. 257/712; 257/99

(57) ABSTRACT

A circuit board comprises a substrate, a plurality of circuit islands, and a plurality of trenches. The circuit islands are formed on the substrate configured for mounting heat-generating devices thereon. The trenches are defined in the substrate configured for increasing a heat dissipation surface area of the substrate. Each of the trenches is arranged between each pair of adjacent circuit islands. A light source device comprises the above circuit board and a plurality of light-emitting diodes is mounted on the circuit island of the circuit board.

### BACKGROUND

1. Technical Field

The present invention relates to circuit boards and light source devices, and more particularly to a circuit board and a light source device both having an enhanced heat dissipation efficiency

2. Description of the Related Art

Light-emitting diodes (LEDs) produce high intensity light. They are widely used in lighting devices and the backlight module for liquid crystal displays. In order to increase light intensity of a backlight module, a plurality of LEDs are densely arranged on a micro circuit board. If the heat generated by the LEDs cannot be dissipated timely, the high temperature of the environment around the LEDs may adversely affect the performance thereof.

A typical light source device 10 is shown in FIG. 1. The light source device 10 includes a plurality of LEDs 14 arranged in high density on a printed circuit board (PCB) 12. The PCB 12 includes a substrate 122 and a plurality of circuit islands 121 formed thereon. Each of circuit islands 121 defines a region for mounting an LED 14. Each of LEDs 14 includes a package 144 and at least two terminals 142. The package 144 is generally made of insulating material with poor heat conductivity. Thus, heat generated by the LEDs 14 cannot be dissipated by the package 144 effectively and is transferred to the PCB 12 via the terminals 142. However, the substrate 122 of the PCB 12 is unsatisfactory for effective heat dissipation and this heat transfer may affect the performance of the PCB.

Another typical light source device 30 having high heat dissipation LEDs 34 is shown in FIG. 2. The light source device 30 includes a PCB 32 and a plurality of LEDs 34 mounted thereon. The PCB 32 includes a metal substrate 324, a top-insulating layer 320, and a bottom-insulating layer 326 coated onto each of the two opposite surfaces of the metal substrate 324. The top-insulating layer 320 is electrically insulative and may be used as an electric insulator between the circuit islands 322 and the metal substrate 324. Each circuit island 322 defines a region for mounting an LED 34. Heat generated by the LED 34 is transferred to the top-insulating layer 320 of the PCB 32 via the terminals 342 and is conducted to the bottom-insulating layer 326 via the metal substrate 324. Thus, the heat can be dissipated by two surfaces of the substrate 32, thus improving heat dissipation efficiency. However, the fact that the LEDs 34 are disposed on the substrate 32 in high density significantly increases the amount of heat generated thereby, surface area for heat dissipation for each LED 34 is limited. Therefore, the above light source device 30 still suffers from the excessive heat accumulated during operation.

What is need, therefore, is a circuit board and a light source device that can increase the efficiency of the heat dissipation.

### SUMMARY

In a preferred embodiment, a circuit board comprises a substrate, a plurality of circuit islands, and a plurality of trenches. The circuit islands are formed on the substrate configured for mounting heat-generating devices thereon. The trenches are defined in the substrate configured for increasing a heat dissipation surface area of the substrate. Each of the trenches is arranged between each pair of adjacent circuit islands.

In another preferred embodiment, a light source device includes a circuit board and a plurality of light-emitting diodes arranged on the circuit board. The circuit board comprises a substrate, a plurality of circuit islands, and a plurality of trenches. The circuit islands are formed on the substrate configured for mounting light-emitting diodes thereon. The trenches are defined in the substrate configured for increasing a heat dissipation surface area of the substrate. Each of the trenches is arranged between each pair of adjacent circuit islands. The light-emitting diodes are mounted on the circuit islands.

Other advantages and novel features will become more apparent from the following detailed description of present circuit board and light source device, when taken in conjunction with the accompanying drawings.

### BRIEF DESCRIPTION OF THE DRAWINGS

Many aspects of the circuit board and its related light source device can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is a schematic, cutaway view of a typical LED light source device;

FIG. 2 is a schematic, cutaway view of another typical LED light source device;

FIG. 3 is a top view of a circuit board, in accordance with a first embodiment;

FIG. 4 is an enlarged, partially cut-away view of the circuit board shown in FIG. 3, taken along the line IV-IV thereof;

FIG. 5 is an enlarged, partially cut-away view of another circuit board, in accordance with a second embodiment;

FIG. 6 is an enlarged, partially cut-away view of a light source device, in accordance with a third embodiment; and

FIG. 7 is an enlarged, partially cut-away view of another light source device, in accordance with a fourth embodiment.

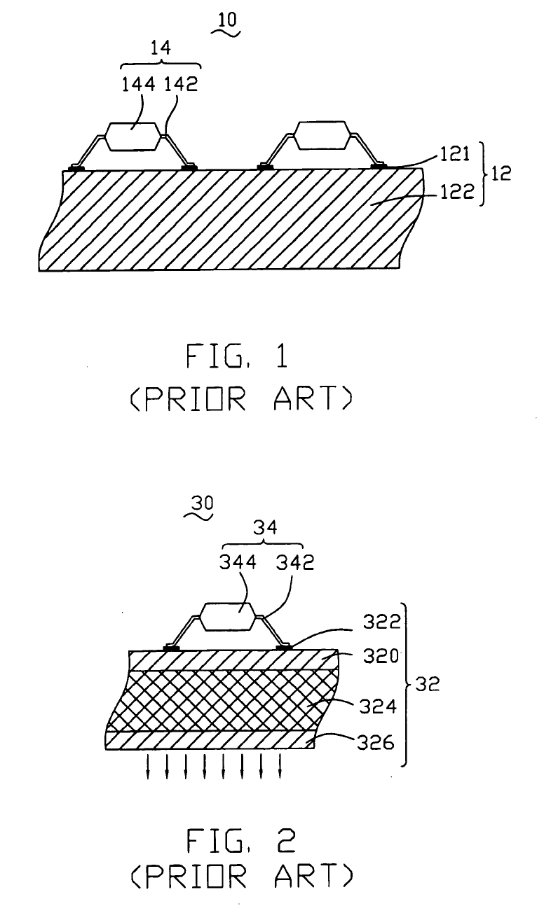

### DETAILED DESCRIPTION OF PREFERRED EMBODIMENTS

Reference will now be made to the drawing figures to describe the embodiments of the present circuit board and light source device in detail.

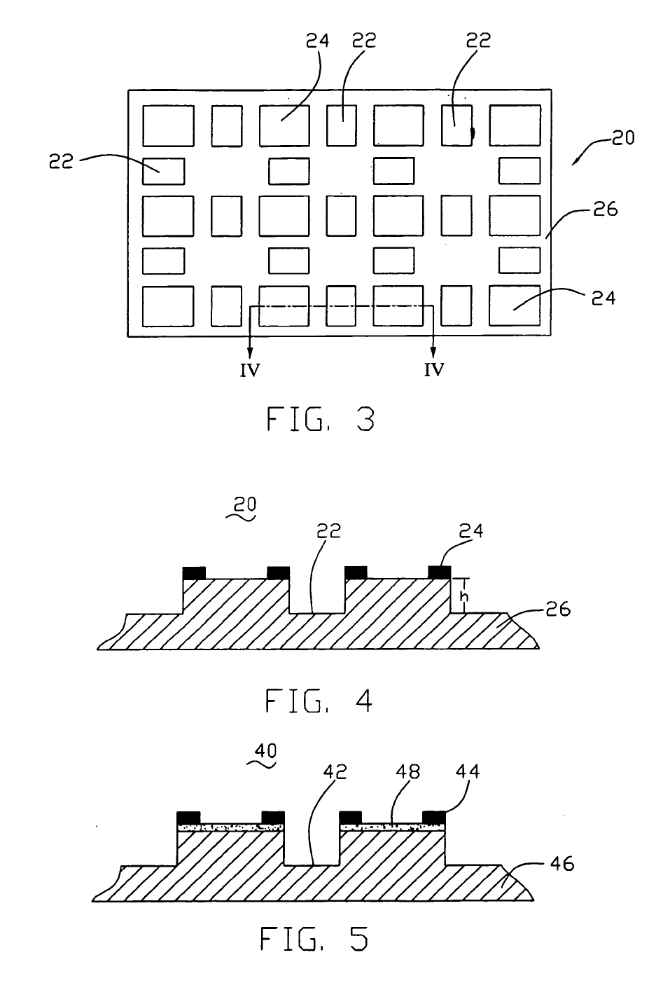

Referring to FIGS. 3 and 4, a circuit board 20 is shown in accordance with a first embodiment. The circuit board 20 includes a substrate 26, a plurality of trenches 22, and a plurality of circuit islands 24.

The substrate 26 is used as a supporting member for supporting the circuit islands 24. The substrate 26 can be made of a metal with high heat conductivity, such as copper, iron, or aluminum.

The circuit islands 24 are formed on a surface of the substrate 26. Each circuit island 24 defines a region for mounting an electronic component e.g. a heat generating device thereon. The circuit islands 24 may be arranged in an array on the substrate 26, according to the practical requirement.

The substrate 26 defines a plurality of trenches 22 on the surface having the circuit islands 24. Each of the trenches 22 is arranged between a pair of adjacent circuit islands 24. An etching process can form the trenches 22. A cross-section of the trench 22 can be, for example, V-shaped, U-shaped, arc-shaped, or rectangular. Preferably, a depth labeled with a reference character h of the trench 22 is in the range from about 10 microns to about 10 millimeters. A surface area of each of the trenches 22 is less than or equal to the area between the adjacent two circuit islands 24.

Due to the use of the trenches 22, a surface area for heat dissipation from the circuit board 20 is increased.

Referring to FIG. 5, another circuit board 40 is shown in accordance with a second embodiment. The circuit board 40 includes a plurality of trenches 42, a plurality of circuit islands 44, a substrate 46, and an insulating layer 48.

The insulating layer 48 is sandwiched between the circuit islands 44 and the substrate 46. The circuit islands 44 are arranged on the insulating 48. Each of the circuit islands 44 defines a region for mounting one electronic component.

The substrate 46 defines a plurality of trenches 42 on the surface having the circuit islands 44. The cross-section and the depth of the trench 42 are similar to or the same as that of the trench 22 in the first embodiment.

The material of the substrate 46 can also be metal with high coefficient of heat conductivity, such as copper, iron, or aluminum.

The insulating layer 48 is used as an electronic insulator of the circuit islands 44 and the substrate 46 and to prevent short circuit between the circuit islands 44 and the substrate 46. Heat can be dissipated via the insulating layer 48. The insulating layer 48 is made of the material with high coefficient of heat conductivity, such as metal oxide or metal nitride. The metal oxide includes aluminum oxide, and the metal nitride may be aluminum nitride.

That the use of the trenches 42 increases a surface area for heat dissipation of the circuit board 40, and an efficiency of heat dissipation is increased accordingly

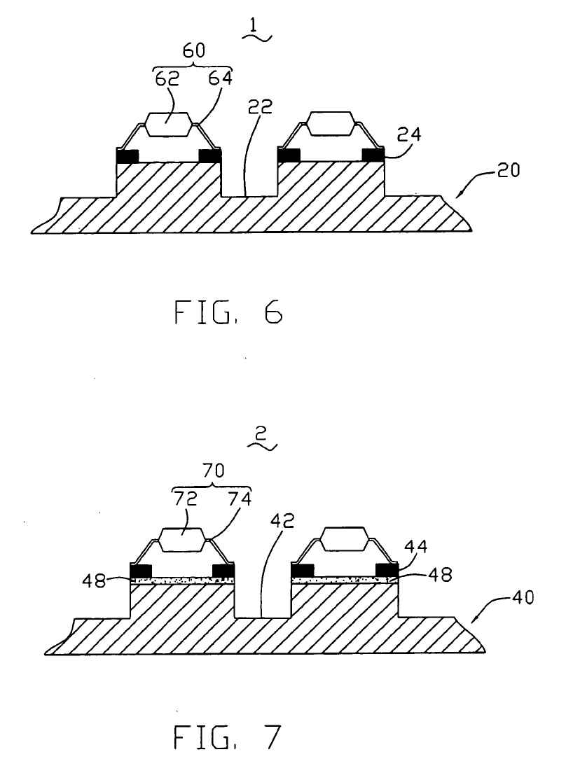

Referring to FIG. 6, a light source device 1 is shown in accordance with a third embodiment. The light source device 1 includes the circuit board 20 and a plurality of electronic components, such as LEDs 60, arranged on the circuit board 20.

Each of the LEDs 60 comprises a package 62 and at least two terminals 64 extending therefrom. Each of the LED 60 is connected with a corresponding circuit island 24 via the terminals 64.

The light source device 1 uses the terminals 64, the package 62, and the trenches 22 to dissipate the heat. The trenches 22 can increase the surface area for heat dissipation of the circuit board 20 and enhance the heat dissipation efficiency of the light source device 1. In addition, the trenches 22 inwardly extend into the circuit board 20, in other words, the LEDs 60 are mounted on an extrusion of the circuit board 20, therefore the light emitted by the LEDs 60 is prevented from being blocked. Furthermore, since each of the LEDs 60 is isolated from a neighboring LED by the trenches 22 each of LEDs 60 forms an independent system. Thus, the LEDs 60 are prevented from interfering each other.

Another light source device 2 is shown in FIG. 7 in accordance with a fourth embodiment. The light source device 2 includes the circuit board 40 and a plurality of LEDs 70 arranged on the circuit board 40.

The LEDs 70 mount on the circuit islands 44. Each of the LEDs 70 comprises a package 72 and at least two terminals 74 extending therefrom. Each of the LEDs 70 is connected with a corresponding circuit island 44 via the terminals 74.

The light source device 2 uses the package 72, the terminals 74, and the trenches 42 to dissipate the heat. The trenches 42 can increase the heating area of the circuit board 40 and enhance the heat dissipation efficiency of the light source device 2.

The trenches 42 can increase surface area for heat dissipation of the circuit board 40 as the trenches 42, substrate 46 and insulating layer 48 all can diffuse the heat generated by the LEDs 70 into the air around the light source device 2. The trenches 42, substrate 46 together with the insulating layer 48 give the circuit board 40 maximum surface area for heat dissipation. Also as the trenches 42 are recessed into the substrate 46 instead of being placed in front of the substrate 46 they avoid blocking the light emitted by the LEDs 70. The trenches 42 separate the LEDs 70 so as to make each LED 70 form an independent system for heat dissipation and thus prevents the LEDs 70 interfering with each other.

Although the present invention has been described with reference to specific embodiments, it should be noted that the described embodiments are not necessarily exclusive, and that various changes and modifications may be made to the described embodiments without departing from the scope of the invention as defined by the appended claims.

What is claimed is:

1. A circuit board comprising:
a substrate including a plurality of circuit islands formed on the substrate configured for mounting a plurality of heat-generating devices thereon; and
a plurality of trenches defined in the substrate configured for increasing a heat dissipation surface area of the substrate, each of the trenches being arranged between each pair of adjacent circuit islands.

2. The circuit board as recited in claim 1, wherein a cross-section of the trench is selected from the group consisting of V-shaped, U-shaped, arc-shaped, and rectangular.

3. The circuit board as recited in claim 1, wherein a depth of the trench is in the range from 10 microns to 10 millimeters.

4. The circuit board as recited in claim 1, wherein a material of the substrate is selected from the group consisting of copper, iron, and aluminum.

5. The circuit board as recited in claim 1, wherein an electrically insulating layer is arranged between the circuit islands and the substrate.

6. The circuit board as recited in claim 5, wherein a material of the electrically insulating layer is metal oxide or metal nitride.

7. A light source device comprising:
a circuit board comprising a substrate including a plurality of circuit islands formed on the substrate, and a plurality of trenches defined in the substrate configured for increasing a heat dissipation surface area of the substrate, each of the trenches being arranged between each pair of adjacent circuit islands; and
a plurality of light-emitting diodes mounted on the circuit islands of the circuit board.

8. The light source device as recited in claim 7, wherein a cross-section of the trench is selected from the group consisting of V-shaped, U-shaped, arc-shaped, and rectangular.

9. The light source device as recited in claim 7, wherein a depth of the trench is in the range from 10 microns to 10 millimeters.

10. The light source device as recited in claim 7, wherein a material of the substrate is selected from the group consisting of copper, iron, and aluminum.

11. The light source device as recited in claim 7, wherein an electrically insulating layer is arranged between the circuit islands and the substrate.

12. The light source device as recited in claim 11, wherein a material of the electrically insulating layer is metal oxide or metal nitride.
